(19) United States
(12) Patent Application Publication
(10) Pub. No.: US 2017/0346033 A1
(43) Pub. Date: Nov. 30, 2017

(54) METHOD FOR PRODUCING AN ORGANIC OPTOELECTRONIC COMPONENT, AND ORGANIC OPTOELECTRONIC COMPONENT

(71) Applicant: OSRAM OLED GmbH, Regensburg (DE)

(72) Inventors: Thomas Wehlus, Lappersdorf (DE); Johannes Rosenberger, Regensburg (DE); Arne Fleissner, Regensburg (DE)

(21) Appl. No.: 15/603,526

(22) Filed: May 24, 2017

(30) Foreign Application Priority Data
May 24, 2016 (DE) 10 2016 109 490.0

(51) Int. Cl. H01L 51/52; H01L 51/44; H01L 51/56

(52) U.S. Cl. CPC H01L 51/5203; H01L 51/56; H01L 51/441; H01L 51/448; H01L 51/5237

(57) ABSTRACT

A method of producing an organic optoelectronic component includes: forming a first electrode layer comprising a contact region, arranging an electrically conductive contact lug on the first electrode layer. A first section of the contact lug is secured in the contact region on the first electrode layer such that a second section projects beyond the contact region. The method further includes forming an organic functional layer structure laterally alongside the contact lug on the first electrode layer, forming a second electrode on the organic functional layer structure, forming an encapsulation layer such that it extends over the second electrode and over the first section, and severing the first electrode layer and the encapsulation layer in the region of the lug such that subsequently the first section is arranged between the contact region and the encapsulation layer and the second section projects between the encapsulation layer and the first electrode layer.

### CROSS-REFERENCE TO RELATED APPLICATION

This application claims priority to German Patent Application Serial No. 10 2016 109 490.0, which was filed May 24, 2016, and is incorporated herein by reference in its entirety.

### TECHNICAL FIELD

Various embodiments relate generally to a method for producing an organic optoelectronic component, and to an organic optoelectronic component.

### BACKGROUND

Optoelectronic components on an organic basis, so-called organic optoelectronic components, are finding increasingly widespread application. By way of example, organic light emitting diodes (OLEDs) are increasingly making inroads into general lighting, for example as surface light sources, or into the automotive sector, for example as interior lighting, rear lights or brake lights. However, organic solar cells and/or organic photodetectors are increasingly being used as well.

An organic optoelectronic component, for example an OLED, may include an anode and a cathode and an organic functional layer system therebetween. The organic functional layer system may include one or a plurality of emitter layers in which electromagnetic radiation is generated, a charge generating layer structure having in each case two or more charge generating layers (CGLs) for charge generation, and one or a plurality of electron blocking layers, also referred to as hole transport layers (HTL), and one or a plurality of hole blocking layers, also referred to as electron transport layers (ETL), in order to direct the current flow.

Organic optoelectronic components are generally encapsulated in order to protect the sensitive organic layers against environmental influences, in particular against oxygen and/or moisture. Examples of conventional encapsulations include cavity encapsulations or thin-film encapsulations, also called encapsulation layers hereinafter. OLEDs having thin-film encapsulations are often used in the automotive sector, for example. In order to be able to make contact with an OLED, for example having an automotive encapsulation, after the thin-film encapsulation has been applied, many complex steps are necessary.

In the case of a monolithically formed OLED, that is to say in the case of an OLED in which lateral side edges of a cover and of a substrate of the OLED are flush with one another, firstly it is necessary to remove the cover of the OLED, for example an aluminum cover, above contact regions for electrically contacting the OLED. Afterward, it is necessary to remove the adhesive with which the cover was secured above the contact regions, for example by a laser. Residues of the adhesive that are possibly then still present above the contact regions have to be removed by laborious manual work. The subsequent processes have to be carried out irrespective of whether or not the OLED is a monolithically formed OLED. If a hard coating is also present as part of the encapsulation, then it is necessary to remove said hard coating, too, above the contact regions, for example by a laser. Afterward, it is necessary to remove the thin-film encapsulation above the contact regions, for example by a laser. As final processes for electrically contacting the OLED, it is then necessary also to secure contact elements on the contact regions, for example by bonding, adhesive bonding or soldering. These processes in each case by themselves and primarily all together are very time-intensive and susceptible to faults.

The exposure of the contact regions and the so-called restructuring of the cover, of the adhesive, of the hard coating and of the encapsulation layer, that is to say of the entire OLED encapsulation, above the contact regions are very complex. As a result, overall the process of electrically contacting the organic optoelectronic component is very complex, time-intensive, cost-intensive and susceptible to faults. This has the consequence that overall the production of organic optoelectronic components, for example for the automotive sector, is very complex, time-intensive and susceptible to faults, as a result of which the production costs are particularly high.

A lateral contacting, that is to say from a lateral side of the organic optoelectronic component, makes it possible, in principle, to be able to dispense with the removal of the cover and of the adhesive for securing the cover. At the lateral side edges, however, the electrode layers or contact layers either are not exposed at all, which forms an obstacle to such contacting, or merely offer a contact area with a height of approximately 800 nm. In the case of such a narrow contact area, however, the contacting is possible only with difficulty or very unreliably.

### SUMMARY

A method of producing an organic optoelectronic component includes: forming a first electrode layer comprising a contact region, arranging an electrically conductive contact lug on the first electrode layer. A first section of the contact lug is secured in the contact region on the first electrode layer such that a second section projects beyond the contact region. The method further includes forming an organic functional layer structure laterally alongside the contact lug on the first electrode layer, forming a second electrode on the organic functional layer structure, forming an encapsulation layer such that it extends over the second electrode and over the first section, and severing the first electrode layer and the encapsulation layer in the region of the lug such that subsequently the first section is arranged between the contact region and the encapsulation layer and the second section projects between the encapsulation layer and the first electrode layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a lateral sectional illustration of a conventional organic optoelectronic component;

FIG. 2 shows a first state during a first embodiment of a method for producing an organic optoelectronic component;

FIG. 3 shows a first state during a second embodiment of a method for producing an organic optoelectronic component;

FIG. 4 shows a second state during the second embodiment of the method for producing the organic optoelectronic component;

FIG. 5 shows a third state during the second embodiment of the method for producing the organic optoelectronic component; and

FIG. 6 shows a fourth state during the second embodiment of the method for producing the organic optoelectronic component.

### DESCRIPTION

In the following detailed description, reference is made to the accompanying drawings, which form part of this description and show for illustration purposes specific exemplary embodiments in which the invention can be implemented. Since component parts of embodiments can be positioned in a number of different orientations, the direction terminology serves for illustration and is not restrictive in any way whatsoever. It goes without saying that other embodiments can be used and structural or logical changes can be made, without departing from the scope of protection of the present invention. It goes without saying that the features of the various embodiments described herein can be combined with one another, unless specifically indicated otherwise. Therefore, the following detailed description should not be interpreted in a restrictive sense, and the scope of protection of the present invention is defined by the appended claims. In the figures, identical or similar elements are provided with identical reference signs, insofar as this is expedient.

An organic optoelectronic component can be an organic electromagnetic radiation emitting component or an organic electromagnetic radiation absorbing component. An organic electromagnetic radiation absorbing component can be for example an organic solar cell. In various exemplary embodiments, an organic electromagnetic radiation emitting component can be an organic electromagnetic radiation emitting semiconductor component and/or be formed as an organic electromagnetic radiation emitting diode or as an organic electromagnetic radiation emitting transistor. The radiation can be for example light in the visible range, UV light and/or infrared light. In this connection, the organic electromagnetic radiation emitting component can be formed for example as an organic light emitting diode (OLED) or as an organic light emitting transistor.

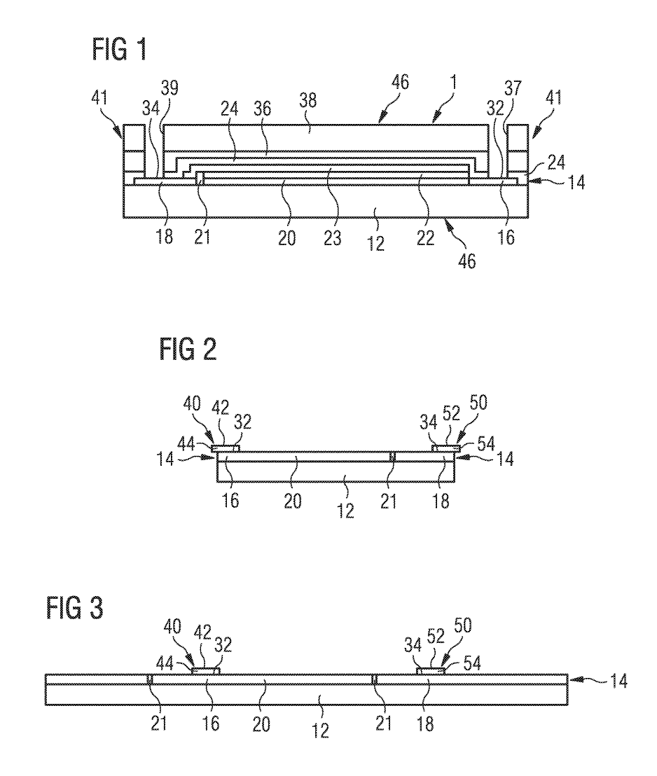

FIG. 1 shows a lateral sectional illustration of a conventional organic optoelectronic component 1.

The conventional organic optoelectronic component 1 includes a carrier 12. The carrier 12 is formed in a transparent fashion and is formed from glass. An optoelectronic layer structure is formed on the carrier 12. The optoelectronic layer structure includes a first electrode layer 14, which includes a first contact section 16, a second contact section 18 and a first electrode 20. The carrier 12 with the first electrode layer 14 can also be referred to as substrate.

The first electrode 20 is electrically insulated from the second contact section 18 by an electrical insulation barrier 21. The first contact section 16 is electrically coupled to the first electrode 20 of the optoelectronic layer structure. The first electrode 20 is formed as an anode. The first electrode 20 is formed in a (optically) transparent fashion. The first electrode 20 includes an electrically conductive material.

An organic functional layer structure 22 of the optoelectronic layer structure is formed above the first electrode 20. The organic functional layer structure 22 includes a plurality of partial layers. The organic functional layer structure 22 includes in particular a hole injection layer, a hole transport layer, an emitter layer, an electron transport layer and/or an electron injection layer.

A second electrode 23 of the optoelectronic layer structure, which is electrically coupled to the second contact section 18, is formed above the organic functional layer structure 22. The second electrode 23 is formed in accordance with the first electrode 20. The second electrode 23 serves as a cathode of the optoelectronic layer structure.

The optoelectronic layer structure is an electrically and optically active region. The active region is for example the region of the conventional organic optoelectronic component 1 in which electric current for the operation of the conventional organic optoelectronic component 1 flows and/or in which electromagnetic radiation is generated or absorbed.

An encapsulation layer 24 of the optoelectronic layer structure, which encapsulates the optoelectronic layer structure, is formed above the second electrode 23 and partly above the first contact section 16 and partly above the second contact section 18. The encapsulation layer 24 can also be referred to as thin-film encapsulation. The encapsulation layer 24 forms a barrier with respect to chemical contaminants and/or atmospheric substances, e.g. with respect to water (moisture), and oxygen.

An adhesion medium layer 36 is formed above the encapsulation layer 24. The adhesion medium layer 36 includes an adhesive. A covering body 38 is formed above the adhesion medium layer 36. The adhesion medium layer 36 serves for securing the covering body 38 on the encapsulation layer 24. The covering body 38 includes metal, in particular aluminum. The covering body 38 serves for protecting the conventional organic optoelectronic component 1, for example against mechanical force influences from outside. Furthermore, the covering body 38 can serve for distributing and/or dissipating heat that is generated in the conventional organic optoelectronic component 1.

In the covering body 38, the adhesion medium layer 36 and the encapsulation layer 24, a first contact cutout 37 is formed above the first contact section 16 and a second contact cutout 39 is formed above the second contact section 18. A first contact region 32 is exposed in the first contact cutout 37 and a second contact region 34 is exposed in the second contact cutout 39. The first contact region 32 serves for electrically contacting the first contact section 16 and the second contact region 34 serves for electrically contacting the second contact section 18.

An underside—at the bottom in FIG. 1—of the carrier 12 and a top side—at the top in FIG. 1—of the covering body 38 form main surfaces of the conventional organic optoelectronic component 1. Via one or both main surfaces 46, the conventional organic optoelectronic component 1 emits and/or absorbs electromagnetic radiation, in particular light. The carrier 12 and the covering body 38, optionally also the encapsulation layer 24 and the adhesion medium layer 36, are formed flush at lateral side surfaces of the conventional organic optoelectronic component 1. The conventional organic optoelectronic component 1 can also be referred to as a monolithic conventional organic optoelectronic component 1, for example as a conventional monolithic OLED.

Forming the contact cutouts 37, 39 and exposing the contact regions 32, 34 in the cutouts 37, 39 after forming the encapsulation, in particular forming the encapsulation layer 24 and the adhesion medium layer 36 and arranging the covering body 38, are very time-consuming, cost-intensive and susceptible to faults. The susceptibility to faults stems from the fact that, in this case, the contact sections 16, 18 can be damaged or sometimes the adhesion medium layer 36 is not completely removed from the contact regions 32, 34, which detrimentally affects the quality of the electrical contacting.

FIG. 2 shows a first state during a first exemplary embodiment of a method for producing an organic optoelectronic component 60, 62 (see FIG. 5 and FIG. 6). In the first state shown in FIG. 2, a carrier 12 is provided. The carrier 12 is formed as translucent or transparent. The carrier 12 serves as a carrier element for electronic elements or layers, for example light emitting elements. The carrier 12 may include or be formed from, for example, plastic, metal, glass, quartz and/or a semiconductor material. Furthermore, the carrier 12 may include or be formed from a plastics film or a laminate including one or a plurality of plastics films. The carrier 12 can be formed in a mechanically rigid fashion or in a mechanically flexible fashion.

A first electrode layer 14 of an optoelectronic layer structure is formed on the carrier 12. A first barrier layer (not illustrated), for example a first barrier thin-film layer, can be formed between the carrier 12 and the first electrode layer 14. The first electrode layer 14 includes a first contact section 16, a second contact section 18 and a first electrode 20. The contact sections 16, 18 are arranged in a manner adjoining lateral side edges of the first electrode layer 14 and of the carrier 12. The carrier 12 with the first electrode layer 14 can also be referred to as substrate.

The first contact section 16 includes a first contact region 32 and the second contact section 18 includes a second contact region 34. The contact regions 32, 34 respectively adjoin a lateral side edge of the first electrode layer 14 and of the carrier 12. The first contact region 32 serves for electrically contacting the first electrode 20. The second contact region 34 serves for electrically contacting the second electrode 23.

The first electrode 20 is electrically insulated from the second contact section 18 by structuring the first electrode layer 14 and forming an electrical insulation barrier 21 between the first electrode 20 and the second contact section 18. The first contact section 16 is electrically coupled to the first electrode 20 of the optoelectronic layer structure. By way of example, the first contact section 16 and the first electrode 20 can be formed integrally. The first electrode 20 can be formed as an anode or as a cathode. The first electrode 20 is formed as translucent or transparent. The first electrode 20 includes an electrically conductive material, for example metal and/or a transparent conductive oxide (TCO) or a layer stack of a plurality of layers including metals or TCOs. The first electrode 20 may include for example a layer stack of a combination of a layer of a metal on a layer of a TCO, or vice versa. One example is a silver layer applied on an indium tin oxide layer (ITO) (Ag on ITO) or ITO-Ag-ITO multilayers. As an alternative or in addition to the materials mentioned, the first electrode 20 may include: networks composed of metallic nanowires and nanoparticles, for example composed of Ag, networks composed of carbon nanotubes, graphene particles and graphene layers and/or networks composed of semiconducting nanowires.

A first contact lug 40 includes a first section 42 and a second section 44. The first section 42 of the first contact lug 40 is secured in the first contact region 32 on the first contact section 16. The second section 44 of the first contact lug 40 projects beyond the first electrode layer 14 in a lateral direction, laterally and horizontally in FIG. 2. The first contact lug 40 is in electrical contact with the first contact section 16 and serves for electrically contacting the first electrode 20.

A second contact lug 50 includes a first section 52 and a second section 54. The first section 52 of the second contact lug 50 is secured in the second contact region 34 on the second contact section 18. The second section 54 of the second contact lug 50 projects beyond the first electrode layer 14 in a lateral direction, laterally and horizontally in FIG. 2. The second contact lug 50 is in electrical contact with the second contact section 18 and serves for electrically contacting the second electrode 23.

The contact lugs 40, 50 enable the contacting of the contact regions 32, 34 already before the formation, e.g. the deposition or printing, of the organic functional layer structure 22.

The contact lugs 40, 50 include electrically conductive material or are formed from electrically conductive material. By way of example, the contact lugs 40, 50 can each include a metal lamina or a metal film or be a metal lamina or a metal film. By way of example, the contact lugs 40, 50, in particular if appropriate the metal lamina or the metal film, may include or be formed by aluminum, copper, palladium and/or gold. As an alternative thereto, the contact lugs 40, 50 can be printed circuit boards.

The contact lugs 40, 50 can each have a thickness in a vertical direction, that is to say for example from the bottom toward the top in the plane of the drawing in FIG. 2, for example of 0.5 μm to 20 μm, for example of 5 μm to 15 μm, for example approximately 10 μm. The contact lugs 40, 50 can each have a width in a lateral direction, that is to say for example from left to right in the plane of the drawing in FIG. 2, for example of 500 μm to 5000 μm, for example of 500 μm to 1500 μm. The contact lugs 40, 50 can each have a depth in a lateral direction, that is to say into the plane of the drawing in FIG. 2, for example of 1 mm up to the total width of the organic optoelectronic component 60, 62, that is to say for example a plurality of centimeters, e.g. 0.01 cm to 10 cm, for example 0.1 cm to 1 cm. The second sections 44, 54 of the contact lugs 40, 50, which project laterally, can each have a width in a lateral direction, that is to say for example from left to right in the plane of the drawing in FIG. 2, for example of 100 μm to 2000 μm, for example of 500 μm to 1000 μm.

The contact lugs 40, 50 can be secured for example by adhesive bonding, ACF bonding or soldering on the corresponding contact sections 16, 18. Optionally, the second sections 44, 54 of the contact lugs 40, 50 can each include an anti-adhesion surface. If appropriate, the anti-adhesion surfaces are formed such that they do not adhere to the first electrode layer 14.

FIG. 3 shows a first state during a second embodiment of a method for producing an organic optoelectronic component 60, 62 (see FIG. 5 and FIG. 6). The first state of the second embodiment of the method for producing the organic optoelectronic component 60, 62 and e.g. the carrier 12, the first electrode layer 14 and the contact lugs 40, 50 largely correspond to the first state of the first embodiment of the method for producing the organic optoelectronic component 60, 62, and carrier 12, first electrode layer 14 and contact lugs 40, 50 as explained with reference to FIG. 2, wherein, in contrast, the carrier 12 and the first electrode layer 14 are provided in such a way that they can serve as a basis for a plurality of organic optoelectronic components 60, 62, e.g. three thereof. Transitions from a part of the carrier 12 and/or of the electrode layer 14 of one of the organic optoelectronic components 60, 62 to a part of the carrier 12 and/or the first electrode layer 14 of another of the organic optoelectronic components 60, 62 are identified by dash-dotted lines in the figures.

The first sections 42, 52 of the contact lugs 40, 50 are secured for example by adhesive bonding, ACF bonding or soldering on the corresponding contact sections 16, 18 or contact regions 32, 34. The second sections 44, 54 of the contact lugs 40, 50 merely bear on the first electrode layer 14, such that they do not adhere to the first electrode layer 14. Optionally, the second sections of the contact lugs 40, 50 each include an anti-adhesion surface. If appropriate, the anti-adhesion surface can face the first electrode layer 14 and/or face away from the first electrode layer 14. The contact lugs 40, 50 are arranged on the first electrode layer 14 in such a way that their first sections 42, 52 are arranged on the central part of the carrier 12 and of the first electrode layer 14 and that their second sections 44, 54 project beyond the transition to the nearest part of the carrier 12 and/or of the first electrode layer 14.

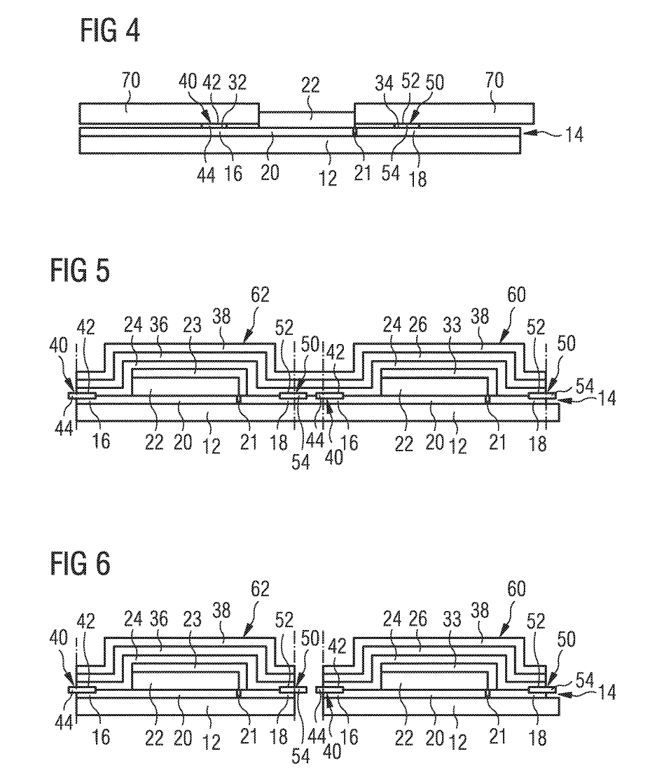

FIG. 4 shows a second state during the second embodiment of the method for producing the organic optoelectronic component 60, 62. The below-explained states of the second embodiment of the method for producing the organic optoelectronic component 60, 62 correspond to the corresponding states during the first exemplary of the method for producing the organic optoelectronic component 60, 62 and can readily be applied thereto, for which reason, in order to avoid unnecessary repetitions, a detailed presentation of the corresponding states of the first method for producing the organic optoelectronic component 60, 62 is dispensed with.

In the second state, a mask 70 is situated above the carrier 12 and the first electrode layer 14. In various embodiments, the mask 70 bears on the contact lugs 40, 50 and completely covers the latter. The mask 70 has a cutout, in which an organic functional layer structure 22 is formed. The organic functional layer structure 22 is formed laterally alongside, e.g. in a lateral direction between, the contact lugs 40, 50 on the first electrode 20, for example by vapor deposition or printing.

The organic functional layer structure 22 may include for example one, two or more partial layers. By way of example, the organic functional layer structure 22 may include a hole injection layer, a hole transport layer, an emitter layer, an electron transport layer and/or an electron injection layer. The hole injection layer serves for reducing the band gap between first electrode and hole transport layer. In the case of the hole transport layer, the hole conductivity is greater than the electron conductivity. The hole transport layer serves for transporting the holes. In the case of the electron transport layer, the electron conductivity is greater than the hole conductivity. The electron transport layer serves for transporting the electrons. The electron injection layer serves for reducing the band gap between second electrode and electron transport layer. Furthermore, the organic functional layer structure 22 may include one, two or more functional layer structure units each including the stated partial layers and/or further intermediate layers.

FIG. 5 shows a third state during the second embodiment of the method for producing the organic optoelectronic component 60, 62. By way of example, FIG. 5 shows a first organic optoelectronic component 60 and a second organic optoelectronic component 62, which are formed on a common carrier 12.

A second electrode 23 of the optoelectronic layer structure, which is electrically coupled to the second contact section 18, is formed above the organic functional layer structure 22. The second electrode 23 can be formed in accordance with one of the configurations of the first electrode 20, wherein the first electrode 20 and the second electrode 23 can be formed identically or differently. The first electrode 20 serves for example as an anode or a cathode of the optoelectronic layer structure. The second electrode 23 serves, in a manner corresponding to the first electrode, as a cathode or an anode of the optoelectronic layer structure.

The optoelectronic layer structure is an electrically and/or optically active region. The active region is for example the region of the organic optoelectronic component 60, 62, in which electric current for the operation of the optoelectronic component 10 flows and/or in which electromagnetic radiation is generated or absorbed. A getter structure (not illustrated) can be arranged on or above the active region. The getter layer can be formed as translucent, transparent or opaque. The getter layer may include or be formed from a material which absorbs and binds substances that are harmful to the active region.

An encapsulation layer 24 of the optoelectronic layer structure, which encapsulates the optoelectronic layer structure, is formed above the second electrode 23 and partly above the first contact section 16 and partly above the second contact section 18. The encapsulation layer 24 can be formed as a second barrier layer, for example as a second barrier thin-film layer. The encapsulation layer 24 can also be referred to as thin-film encapsulation. The encapsulation layer 24 forms a barrier with respect to chemical contaminants and/or atmospheric substances, in particular with respect to water (moisture) and oxygen. The encapsulation layer 24 can be formed as a single layer, a layer stack or a layer structure. The encapsulation layer 24 may include or be formed from: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, poly(p-phenylene terephthalamide), Nylon 66, and mixtures and alloys thereof. If appropriate, the first barrier layer can be formed on the carrier 12 in a manner corresponding to a configuration of the encapsulation layer 24.

An adhesion medium layer 36 is formed above the encapsulation layer 24. The adhesion medium layer 36 includes for example an adhesion medium, for example an adhesive, for example a lamination adhesive, a lacquer and/or a resin. The adhesion medium layer 36 may include for example particles which scatter electromagnetic radiation, for example light-scattering particles. Optionally, the adhesion medium layer 36 can be formed as a hard coating and thus form a part of the encapsulation.

A covering body 38 is formed above the adhesion medium layer 36. The adhesion medium layer 36 serves for securing the covering body 38 on the encapsulation layer 24. The covering body 38 includes for example plastic, glass and/or metal. By way of example, the covering body 38 can substantially be formed from glass and include a thin metal layer, for example a metal film, and/or a graphite layer, for example a graphite laminate, on the glass body. The covering body 38 serves for protecting the organic optoelectronic components 60, 62, for example against mechanical force influences from outside. Furthermore, the covering body 38 can serve for distributing and/or dissipating heat that is generated in the organic optoelectronic components 60, 62. By way of example, the glass of the covering body 38 can serve as protection against external influences and the metal layer of the covering body 38 can serve for distributing and/or dissipating the heat that arises during the operation of the organic optoelectronic components 60, 62.

In the third state, the encapsulation layer 24, the adhesion medium layer 36 and the covering body 38 still extend integrally over the organic optoelectronic components 60, 62. The contact lugs 40, 50 are arranged in each case such that their first sections 42, 52 are arranged in the region of the corresponding organic optoelectronic components 60, 62, e.g. in the contact regions 32, 34 thereof, and that their second sections 44, 54 project beyond the corresponding organic optoelectronic component 60, 62, e.g. the contact regions 32, 34 thereof. In various embodiments, the second sections 44, 54 project into a region between the two organic optoelectronic components 60, 62. As an alternative thereto, the second sections 44, 54 can project across to the adjacent organic optoelectronic component 60, 62.

FIG. 6 shows a fourth state during the second embodiment of the method for producing the organic optoelectronic component 60, 62. In the fourth state, the organic optoelectronic components 60, 62 have been singulated, e.g. separated from one another. The singulation or the separation of the organic optoelectronic components 60, 62 can be carried out by example by means of cutting, for example by a laser, or by sawing.

By way of example, during singulation, it is possible firstly for only the covering body 38 to be cut by a laser. The carrier 12 can then be severed, for example by means of scribing in the case of a glass carrier. Afterward, the individual organic optoelectronic components 60, 62 and residual pieces are present. Since the adhesion of the contact lugs 40, 50 to the residual pieces is only very low, they are simply pulled from the material of the residual pieces and then project laterally below the encapsulation of organic optoelectronic components 60, 62. Since the contact lugs 40, 50 are electrically conductive, they can then be electrically contacted in a simple manner. By way of example, the second sections 44, 54 of the contact lugs 40, 50 can be grasped by means of a simple clamping mechanism which, in a simple manner, penetrates through TFE residues etc. possibly still present and optionally plastically or elastically deforms the contact lugs 40, 50 for the purpose of better connection.

An underside—at the bottom in FIG. 6—of the carrier 12 and a top side—at the top in FIG. 6—of the covering body 38 form main surfaces of the organic optoelectronic components 60, 62. Via the underside, the organic optoelectronic components 60, 62 emit and/or absorb electromagnetic radiation, e.g. light. The carrier 12 and the covering body 38, optionally also the encapsulation layer 24 and the adhesion medium layer 36, are formed respectively flush with one another at lateral side surfaces of the organic optoelectronic components 60, 62. The organic optoelectronic components 60, 62 can also be referred to as monolithic organic optoelectronic components 60, 62, for example as monolithic OLEDs. The contact lugs 40, 50 enable in each case simple, rapid and direct contacting of the organic optoelectronic components 60, 62, e.g. of the monolithic OLEDs.

The embodiments are not restricted to the embodiments indicated. By way of example, more than just one or more than two organic optoelectronic components 60, 62 can be formed above a common integral carrier 12.

Various embodiments provide a method for producing an organic optoelectronic component which can be carried out particularly simply, rapidly, reliably and/or cost-effectively.

Various embodiments provide an organic optoelectronic component which can be produced particularly simply, rapidly, reliably and/or cost-effectively.

Various embodiments provide a method for producing an organic optoelectronic component, wherein: a first electrode layer is formed, which includes a contact region, an electrically conductive contact lug, which includes a first section and a second section, is arranged on the first electrode layer, wherein the first section of the contact lug is secured in the contact region on the first electrode layer such that the second section of the contact lug projects beyond the contact region, an organic functional layer structure is formed laterally alongside the contact lug on the first electrode layer, a second electrode is formed on the organic functional layer structure; an encapsulation layer is formed such that it extends over the second electrode and over the first section of the contact lug, and the first electrode layer and the encapsulation layer are severed in the region of the contact lug such that subsequently the first section of the contact lug is arranged between the contact region and the encapsulation layer and the second section projects between the encapsulation layer and the first electrode layer.

The contact lug and thus the electrical contact of the organic optoelectronic component are formed before the organic functional layer structure, the second electrode and the encapsulation are formed, in particular before the process of forming the encapsulation layer, if appropriate a hard coating, and the adhesion medium layer and/or before the process of arranging a covering body, for example a cover. The processes explained in the introduction for exposing the contact regions and for restructuring the encapsulation of the organic optoelectronic component may be omitted as a result. By way of example, the removal of the cover and of the adhesive for securing the cover, if appropriate of the hard coating and also of the thin-film encapsulation above the contact regions is omitted. Moreover, electrical contacting by bonding, adhesive bonding or soldering may be omitted or at least simplified.

As a result, overall the process of electrically contacting the organic optoelectronic component can be carried out very simply, rapidly, cost-effectively and with little susceptibility to faults. This has the consequence that overall the method for producing the organic optoelectronic component is very simple, rapid, cost-effective and has little susceptibility to faults, as a result of which the production costs are particularly low and the reliability is particularly high. By way of example, precisely for the automotive sector it is thus possible for high-quality organic optoelectronic components, for example OLEDs, having high-quality thin-film encapsulations (TFEs) to be produced expediently, without complex restructuring of the corresponding TFE layers.

The first section of the contact lug can be secured for example by conductive adhesive or by means of ACF (anisotropic conductive film) bonding in the contact region. Optionally, the first electrode layer can be formed on a carrier. Furthermore, a covering body, for example a cover, can be arranged on the encapsulation layer, for example by an adhesion medium layer. The adhesion medium layer can optionally be formed as a hard coating and form a part of the encapsulation.

In accordance with one development, the contact lug is secured exclusively in the contact region on the first electrode layer. This has the effect that exclusively the first section of the contact lug is secured on the contact region and that the contact lug, where it projects beyond the contact region, that is to say with its second section, is not secured on the first electrode layer. This has the effect that upon removal of the first electrode layer, the second section of the contact lug is automatically exposed in a particularly simple manner.

In accordance with one development, the second section of the contact lug includes an anti-adhesion surface constituted such that the second section of the contact lug adheres neither to the first electrode layer nor to the encapsulation layer. This has the effect that the encapsulation layer and the first electrode layer do not adhere to the second section of the contact lug projecting beyond the contact region. This has the effect that upon removal of the first electrode layer and/or of the encapsulation layer, the second section of the contact lug is automatically exposed in a particularly simple manner. The anti-adhesion surface can be formed, for example, by the corresponding surface of the contact lug being machined, for example ground or polished. As an alternative thereto, the second section of the contact lug can be coated with an anti-adhesion layer, which then forms the anti-adhesion surface. The anti-adhesion surface includes a material or is constituted such that it does not adhere to the first electrode layer and/or such that the encapsulation layer does not adhere to it. If the encapsulation of the organic optoelectronic component includes a hard coating, then the anti-adhesion surface can be formed such that the material of the hard coating does not adhere to the anti-adhesion surface.

As an alternative thereto, the second contact lug may include a peelable film in the second section. In the process of forming the organic functional layer structure, the latter is deposited onto the peelable film. If the organic functional layer structure is intended subsequently to be removed from the second section, then this is possible in a simple manner since, in this case, only the peelable film adheres to the organic functional layer structure and can be peeled off the second section of the contact lug in a simple manner.

In accordance with one development, the second section of the contact lug is secured by a releasable adhesive on the first electrode layer. This can contribute to the fact that, during the method for producing the organic optoelectronic component, the contact lug firstly has a good adhesion to the first electrode layer, but then can be removed in a simple manner by releasing the adhesive. The releasable adhesive can be released for example by means of heat or by UV radiation.

In accordance with one development, the contact lug is formed as a printed circuit board. This can contribute to the fact that the contact lug can be formed particularly simply and/or cost-effectively and/or that two, three or more different electrical contacts, for example electrically insulated from one another, can be electrically contacted independently of one another by a single contact lug. By way of example, the corresponding printed circuit board may include two, three or more conductor tracks electrically insulated from one another and the contact region may accordingly include two, three or more contacts electrically insulated from one another, which contacts can be electrically contacted independently of one another by means of the corresponding conductor tracks.

In accordance with one development, a further organic optoelectronic component is produced at the same time as the organic optoelectronic component, wherein the first electrode layer extends over both organic optoelectronic components, wherein the contact region is arranged on a lateral edge of the organic optoelectronic component and wherein the second section of the contact lug is arranged between both organic optoelectronic components or in the region of the further organic optoelectronic component. If the first electrode layer is formed on a carrier, then the carrier can also extend over the two organic optoelectronic components. Furthermore, more than two organic optoelectronic components can be produced at the same time, wherein the corresponding organic optoelectronic components include a common carrier and/or a common first electrode layer. After the organic optoelectronic components have been largely completed, they can then be singulated and separated from one another. The fact that the contact region is arranged at the lateral edge of the organic optoelectronic component and the fact that the second section of the contact lug is arranged between the two organic optoelectronic components or in the region of the further organic optoelectronic component have the effect that after the organic optoelectronic components have been singulated and separated, the second section of the contact lug protrudes outward from the other layers. This has the effect that the organic optoelectronic component, in particular the contact lug, is electrically contactable in a particularly simple manner. In various embodiments, a lateral contact, e.g. the second section of the contact lug, is already accessible in a simple manner directly after singulation.

In accordance with one development, the first electrode layer is structured such that it subsequently includes a first electrode and a first contact section for electrically contacting the first electrode and laterally alongside a second contact section for electrically contacting the second electrode, wherein the second contact section is separated from the first electrode and the first contact section and wherein the first contact section or the second contact section includes the contact region in which the first section of the contact lug is secured. In other words, from the first electrode layer, in addition to the first electrode, two mutually independent contact sections are formed, one for electrically contacting the first electrode and one for electrically contacting the second electrode, wherein at least one of the contact sections is electrically contacted by means of the contact lug.

In accordance with one development, the contact lug is a first contact lug, the contact region is a first contact region on the first contact section, and the second contact section includes a second contact region. An electrically conductive second contact lug including a first section and a second section is arranged on the first electrode layer, wherein the first section of the second contact lug is secured in the second contact region on the first electrode layer such that the second section of the second contact lug projects beyond the second contact region. The encapsulation layer is formed such that it extends over the first section of the second contact lug. The first electrode layer and the encapsulation layer are severed in the region of the second contact lug such that the first section of the second contact lug is arranged between the second contact region and the encapsulation layer and the second section of the second contact lug projects between the encapsulation layer and the first electrode layer. In other words, the organic optoelectronic component includes the first contact section having the first contact region for electrically contacting the first electrode and the second contact section having the second contact region for electrically contacting the second electrode, wherein the first contact lug electrically contacts the first contact region and the second contact lug electrically contacts the second contact region.

Various embodiments provide the organic optoelectronic component, including: the first electrode layer, which includes the contact region; the electrically conductive contact lug, which includes the first section and the second section, on the first electrode layer, wherein the first section of the contact lug is secured in the contact region on the first electrode layer and the second section of the contact lug projects beyond the contact region; the organic functional layer structure on the first electrode layer and laterally alongside the contact lug; the second electrode on the organic functional layer structure; and the encapsulation layer, which extends over the second electrode and over the first section of the contact lug; wherein the first section of the contact lug is arranged between the contact region and the encapsulation layer and the second section projects outward between the first electrode layer and the encapsulation layer.

The developments and/or effects explained above in association with the method for producing the organic optoelectronic component can readily be applied to the organic optoelectronic component, for which reason a renewed presentation of the developments and/or advantages is dispensed with here and in this context reference is merely made to the explanations above.

In accordance with one development, the contact lug is secured exclusively in the contact region on the first electrode layer.

In accordance with one development, the second section of the contact lug includes the anti-adhesion surface.

In accordance with one development, the contact lug is formed as a printed circuit board.

In accordance with one development, the first electrode layer includes the first electrode and the first contact section for electrically contacting the first electrode and laterally alongside the second contact section for electrically contacting the second electrode, wherein the second contact section is separated from the first electrode and the first contact section and wherein the first contact section or the second contact section includes the contact region in which the first section of the contact lug is secured.

In accordance with one development, the contact lug is the first contact lug and the contact region is the first contact region for electrically contacting the first electrode, and the second contact section includes the second contact region. The electrically conductive second contact lug includes the first section and the second section and is arranged on the first electrode layer. The first section of the second contact lug is secured in the second contact region on the first electrode layer such that the second section of the second contact lug projects beyond the second contact region. The encapsulation layer is formed such that it extends over the first section of the second contact lug. The first section of the second contact lug is arranged between the second contact region and the encapsulation layer and the second section of the second contact lug projects outward between the first electrode layer and the encapsulation layer.

In accordance with one development, the first electrode layer is formed on a carrier and a covering body is arranged above the encapsulation layer, wherein lateral outer edges of the carrier and of the covering body are flush with one another. The organic optoelectronic component formed in this way can also be referred to as a monolithic organic optoelectronic component.

### LIST OF REFERENCE SIGNS

Organic optoelectronic component 10

Carrier 12

First electrode layer 14

First contact section 16

Second contact section 18

First electrode 20

Insulation barriers 21

Organic functional layer structure 22

Second electrode 23

Encapsulation layer 24

First contact region 32

Second contact region 34

Adhesion medium layer 36

Covering body 38

First contact cutout 37

Second contact cutout 39

First contact lug 40

Lateral side surfaces 41

First section of the first contact lug 42

Second section of the first contact lug 44

Second contact lug 50

First section of the second contact lug 52

Second section of the second contact lug 54

First organic optoelectronic component 60

Second organic optoelectronic component 62

Mask 70

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of producing an organic optoelectronic component, the method comprising:
forming a first electrode layer, which comprises a contact region;
arranging an electrically conductive contact lug, which comprises a first section and a second section, on the first electrode layer, wherein the first section of the contact lug is secured in the contact region on the first electrode layer such that the second section of the contact lug projects beyond the contact region;
forming an organic functional layer structure laterally alongside the contact lug on the first electrode layer;
forming a second electrode on the organic functional layer structure;
forming an encapsulation layer such that it extends over the second electrode and over the first section of the contact lug; and
severing the first electrode layer and the encapsulation layer in the region of the contact lug such that subsequently the first section of the contact lug is arranged between the contact region and the encapsulation layer and the second section projects between the encapsulation layer and the first electrode layer.

2. The method of claim 1,
wherein the contact lug is secured exclusively in the contact region on the first electrode layer.

3. The method of claim 1,
wherein the second section of the contact lug comprises an anti-adhesion surface constituted such that the second section of the contact lug adheres neither to the first electrode layer nor to the encapsulation layer.

4. The method of claim 1,
wherein the second section of the contact lug is secured by means of a releasable adhesive on the first electrode layer.

5. The method of claim 1,
wherein the contact lug is formed as a printed circuit board.

6. The method of claim 1,
wherein a further organic optoelectronic component is produced at the same time as the organic optoelectronic component, wherein the first electrode layer extends over both organic optoelectronic components, wherein the contact region is arranged on a lateral edge of the organic optoelectronic component and wherein the second section of the contact lug is arranged between both organic optoelectronic components or in the region of the further organic optoelectronic component (62).

7. The method of claim 1,
wherein the first electrode layer is structured such that it subsequently comprises a first electrode and a first contact section for electrically contacting the first electrode and laterally alongside a second contact section for electrically contacting the second electrode, wherein the second contact section is separated from the first electrode and the first contact section and wherein the first contact section or the second contact section comprises the contact region in which the first section of the contact lug is secured.

8. The method of claim 7,
wherein the contact lug is a first contact lug;
wherein the contact region is a first contact region on the first contact section;
wherein the second contact section comprises a second contact region;
wherein an electrically conductive second contact lug comprising a first section and a second section is arranged on the first electrode layer, wherein the first section of the second contact lug is secured in the second contact region on the first electrode layer such that the second section of the second contact lug projects beyond the second contact region;
the encapsulation layer is formed such that it extends over the first section of the second contact lug; and
the first electrode layer and the encapsulation layer are severed in the region of the second contact lug such that the first section of the second contact lug is arranged between the second contact region and the encapsulation layer and the second section of the second contact lug projects between the encapsulation layer and the first electrode layer.

9. An organic optoelectronic component, comprising
a first electrode layer, which comprises a contact region;
an electrically conductive contact lug, which comprises a first section and a second section, on the first electrode layer, wherein the first section of the contact lug is secured in the contact region on the first electrode layer and the second section of the contact lug projects beyond the contact region;
an organic functional layer structure on the first electrode layer and laterally alongside the contact lug;
a second electrode on the organic functional layer structure; and
an encapsulation layer, which extends over the second electrode and over the first section of the contact lug;
wherein the first section of the contact lug is arranged between the contact region and the encapsulation layer and the second section projects outward between the first electrode layer and the encapsulation layer.

10. The organic optoelectronic component of claim 9,
wherein the contact lug is secured exclusively in the contact region on the first electrode layer.

11. The organic optoelectronic component of claim 9,
wherein the second section of the contact lug comprises an anti-adhesion surface.

12. The organic optoelectronic component of claim 9,
wherein the contact lug is formed as a printed circuit board.

13. The organic optoelectronic component of claim 9,
wherein the first electrode layer comprises a first electrode and a first contact section for electrically contacting the first electrode and laterally alongside a second contact section for electrically contacting the second electrode, wherein the second contact section is separated from the first electrode and the first contact section and wherein the first contact section or the second contact section comprises the contact region in which the first section of the contact lug is secured.

14. The organic optoelectronic component of claim 13,
wherein the contact lug is a first contact lug and the contact region is a first contact region for electrically contacting the first electrode;
wherein the second contact section comprises a second contact region;
wherein an electrically conductive second contact lug comprising a first section and a second section is arranged on the first electrode layer, wherein the first section of the second contact lug is secured in the second contact region on the first electrode layer such that the second section of the second contact lug projects beyond the second contact region;
wherein the encapsulation layer is formed such that it extends over the first section of the second contact lug; and
wherein the first section of the second contact lug is arranged between the second contact region and the encapsulation layer and the second section of the second contact lug projects outward between the first electrode layer and the encapsulation layer.

15. The organic optoelectronic component of claim 9,
wherein the first electrode layer is formed on a carrier and a covering body is arranged above the encapsulation layer, wherein lateral outer edges of the carrier and of the covering body are flush with one another.
